(19) United States
(12) Patent Application Publication
(10) Pub. No.: US 2009/0026624 A1
(43) Pub. Date: Jan. 29, 2009

(54) SEMICONDUCTOR DEVICE AND METHOD FOR MANUFACTURING METAL LINE THEREOF

(76) Inventor: Yong-Geun Lee, Eumseong-gun (KR)

Correspondence Address: SHERR & VAUGHN, PLLC, 620 HERNDON PARKWAY, SUITE 200, HERNDON, VA, 20170, US

(21) Appl. No.: 12/175,719

(22) Filed: Jul. 18, 2008

(30) Foreign Application Priority Data
Jul. 25, 2007 (KR) 10-2007-0074599

(51) Int. Cl. H01L 23/48; H01L 21/44

(52) U.S. Cl. 257/762; 438/681; 257/E23.01; 257/E21.476

(57) ABSTRACT

A method for manufacturing a metal line of a semiconductor device includes forming an interlayer dielectric layer over the whole surface of a semiconductor substrate including a first metal line. A plurality of trenches are formed in trench areas each having a predetermined depth from a surface thereof by selectively removing portions of the interlayer dielectric layer. A first metal film is formed in the plurality of trenches. A first photoresist pattern is formed over the interlayer dielectric layer exposing contact areas and the first metal line. Via holes are formed in the contact areas by etching the interlayer dielectric layer using the first photoresist pattern and the first metal film as masks. A second metal film is formed in the via holes. Accordingly, misalignment of masks caused during formation of the metal line can be restrained, thereby minimizing the defect rate and improving yield.

The present application claims priority under 35 U.S.C. 119 to Korean Patent Application No. 10-2007-0074599 (filed on Jul. 25, 2007), which is hereby incorporated by reference in its entirety.

### BACKGROUND

In manufacturing a semiconductor device, aluminum and aluminum alloys are most generally used as a metal constituting the semiconductor device since they have excellent electric conductivity and excellent adhesion to an oxide layer. Furthermore, aluminum is easy to shape.

However, use of the aluminum and the aluminum alloy has some problems in terms of electro migration, hillock, spike and so on. More specifically, when applying a current to a metal line made of aluminum, aluminum atoms are diffused at high-current density areas such as a silicon-contacting area or a stepped area. The metal line may be thinned at the portion of diffusion and finally shorted. This is called electro-migration. Since diffusion of atoms by electro-migration progresses incrementally, device malfunction actually occurs after a considerable time from the beginning of device operation.

To solve this problem, an aluminum-copper alloy, formed by adding a little copper to aluminum, may be applied. Also, the problem can be overcome by improving step coverage and expanding the silicon-contacting area sufficiently.

There is another problem generated during an alloying process. When a thermal process is being performed, electro-migration from silicon to an aluminum film may be generated. The device may be broken due to overreaction in certain places, which is called a spike.

A spike may be overcome by adopting an aluminum-silicon alloy which contains silicon by more than a soluble degree. A spike may also be overcome by applying a diffusion barrier formed by inserting a thin film of metal such as TiW or PtSi between aluminum and silicon. Because of these problems, there has been an increasing need for a substitute material for the aluminum metal line. Metals including Cu (copper), Au, Ag, Co, Cr and Ni, with excellent conductivity, can be applied as the substitute. Among these materials, copper and a copper alloy are widely used because of a relatively low specific resistance, a high reliability in electro-migration and stress migration, and a low production price.

The copper and the copper alloy may be processed by vapor deposition of copper in a via-hole (or contact hole) and a trench having a dual damascene structure, thereby forming a plug and a metal line simultaneously. Residual copper remaining on the surface of a wafer is removed through chemical mechanical planarization (CMP). However, the copper may be difficult to planarize since it is easily oxidized and dissolved by a slurry used for the planarization process.

Hereinafter, a related method for manufacturing a metal line of a semiconductor device will be described with the accompanying drawings. FIG. 1A through FIG. 1F are sectional views illustrating the processes for manufacturing a metal line, according to the related art. As shown in FIG. 1A, a first copper thin film may be formed over a semiconductor substrate 11 and selectively removed by a photo-etching process. Accordingly, a first copper line 12 is formed.

Next, a silicon nitride film 13 may be formed over the whole surface of the semiconductor substrate 11 including the first copper line 12. An interlayer dielectric 14 may be formed over the silicon nitride film 13. Here, the silicon nitride film 13 may be used as an etching mask. The interlayer dielectric 14 may include an oxide film. A first photoresist 15 may be applied over the interlayer dielectric 14, and then patterned by lithography and development, thereby defining contact areas. Using the patterned first photoresist 15 as a mask and the silicon nitride film 13 as an etch end point, the interlayer dielectric 14 may be selectively removed to form via holes 16.

Referring to FIG. 1B, the first photoresist 15 may be removed and then a second photoresist 17 may be applied over the whole surface of the semiconductor substrate 11 including the via holes 16. After that, the second photoresist 17 may be patterned through lithography and development such that the second photoresist 17 remains only in the via holes 16.

As shown in FIG. 1C, a third photoresist 18 may be applied to the whole surface of the semiconductor substrate 11 and then patterned through lithography and development to thereby define trench areas. Next, using the patterned third photoresist 18 as a mask, the interlayer dielectric 14 may be selectively removed to a predetermined depth from a surface thereof. Accordingly, trenches 19 are formed.

As shown in FIG. 1D, the second and the third photoresists 17 and 18 may be removed. Then, using the interlayer dielectric 14 as a mask, the silicon nitride film 13 exposed in the bottom of the via holes 16 may be etched off.

Referring to FIG. 1E, after a copper seed layer is formed over the whole surface of the semiconductor substrate 11 including the trenches 19 and the via holes 16, a second copper thin film 21a may be formed using an electroplating method. Although not illustrated in the drawings, the second copper thin film 21a may be manufactured by forming a barrier metal film formed of a conductive material such as Ti or TiN, over the whole surface of the semiconductor substrate 11 that includes the trenches 19 and the via holes 16, and then forming the copper seed layer over the barrier metal film.

As shown in FIG. 1F, setting an upper surface of the interlayer dielectric 14 as a polishing stop, a CMP process may be performed to selectively remove the second copper thin film 21a and the barrier metal film, thereby forming a second copper line 21 within the trenches 19 and the via holes 16.

However, according to the related method as described above, pluralities of the via holes 16 and the trenches 19 may be misaligned. More specifically, when forming a plurality of the via holes 16 as shown in FIG. 1A and forming a plurality of the trenches 19 as shown in FIG. 1C, if any one mask is misaligned, the via holes 16 and the trenches 19 are arranged in the wrong positions, deviating from the contact positions. In this case, as shown in FIG. 2, the trenches 19 neighboring each other may cause a short circuit. In other words, the neighboring second copper lines 21 may be brought into contact with each other or shorted with the first copper line 12.

### SUMMARY

Embodiments relate to a semiconductor device, and more particularly, to a semiconductor device and a method for manufacturing a metal line thereof, capable of improving a production yield rate by minimizing the defect rate especially during manufacturing of the metal line. Embodiments relate to a method for manufacturing a metal line of a semiconductor device including forming an interlayer dielectric layer over the whole surface of a semiconductor substrate including a first metal line. A plurality of trenches are formed in trench areas each having a predetermined depth from a surface thereof by selectively removing portions of the interlayer dielectric layer. A first metal film is formed in the plurality of trenches. A first photoresist pattern is formed over the interlayer dielectric layer exposing contact areas and the first metal line. Via holes are formed in the contact areas by etching the interlayer dielectric layer using the first photoresist pattern and the first metal film as masks. A second metal film is formed in the via holes.

Embodiments relate to a semiconductor device which includes an interlayer dielectric layer formed over the whole surface of a semiconductor substrate including a first metal line. A first metal film is formed in trench areas to a predetermined depth from a surface of the interlayer dielectric layer. A second metal film is formed in contact areas disposed between the trench areas so as to be connected to the first metal film and the first metal line. The first metal film and the second metal film form a second metal line connected to the first metal line.

### DRAWINGS

FIG. 1A through FIG. 1F are sectional views illustrating the processes for manufacturing a metal line according to the related art.

FIG. 2 is a sectional view showing a problem generated in a metal line of a semiconductor device according to the related art.

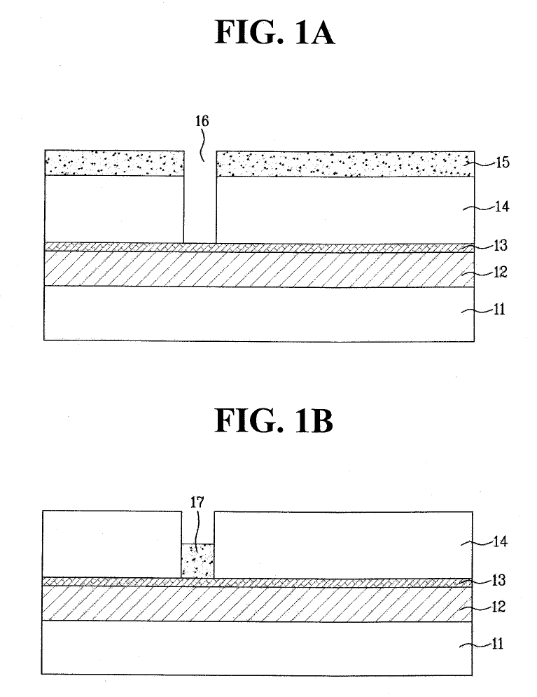

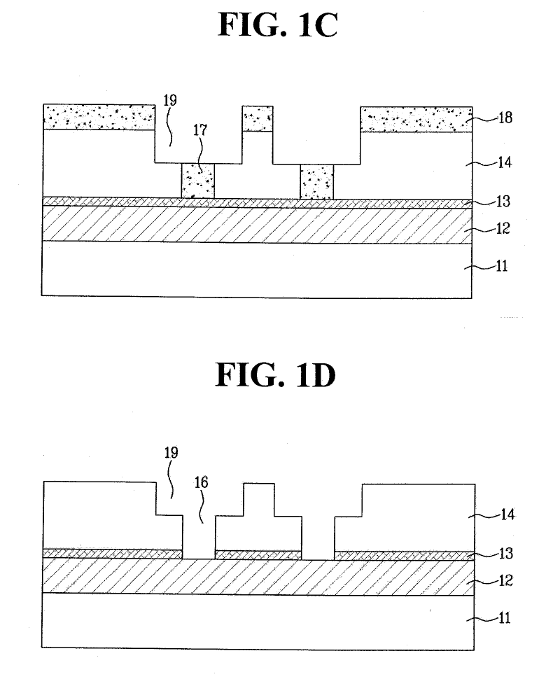

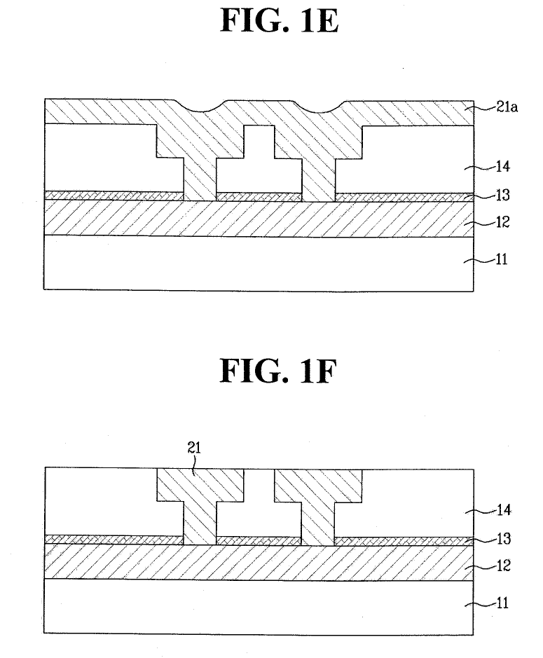

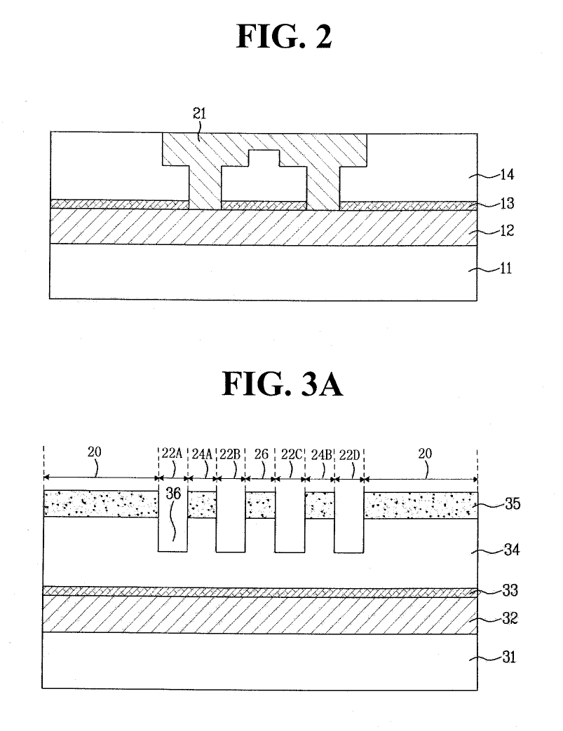

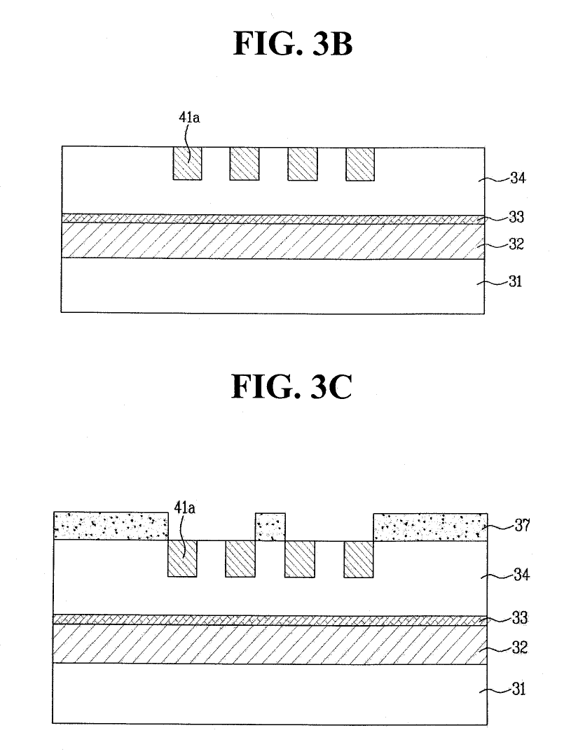

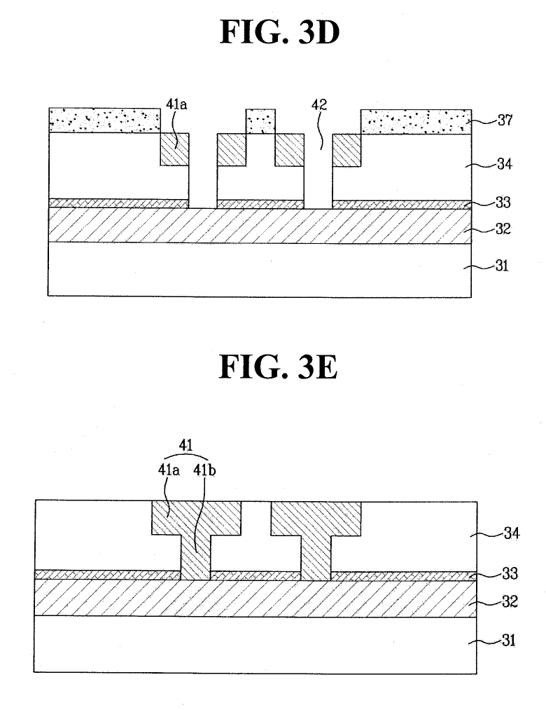

Example FIG. 3A through example FIG. 3E are sectional views illustrating the processes for manufacturing a metal line of a semiconductor device according to embodiments.

### DESCRIPTION

Example FIG. 3A through example FIG. 3E are sectional views illustrating the processes for manufacturing a metal line of a semiconductor device according to embodiments. Referring to example FIG. 3A, a first copper thin film may be formed over a semiconductor substrate 31 or a dielectric layer. The first copper thin film may be selectively removed through lithography and development to form a first copper line 32.

A silicon nitride film 33 may be formed over the whole surface of the semiconductor substrate 31 including the first copper line 32. An interlayer dielectric 34 may be formed over the silicon nitride film 33. The silicon nitride film 33 may be used as an etching mask. The interlayer dielectric 34 may include an oxide layer, fluoro-silicate glass (FSG) or a low K material.

Next, a first photoresist 35 may be applied over the interlayer dielectric 34 and then patterned through lithography and development. Accordingly, trench areas 22A, 22B, 22C and 22D and contact areas 24A and 24B are respectively defined. Here, the first photoresist 35 may be removed from the trench areas 22A, 22B, 22C and 22D by patterning, but remains in the other areas 20 and 26 excluding the trench areas 22A, 22B, 22C and 22D, and in the contact areas 24A and 24B. Using the patterned first photoresist 35 as a mask, the interlayer dielectric 34 may be selectively removed. More specifically, the interlayer dielectric 34 may be removed from the trench areas 22A, 22B, 22C and 22D to a predetermined depth with respect to a surface thereof. Thus, first trenches 36 may be formed to a predetermined depth. Here, thickness of the interlayer dielectric 34 remaining at a lower part of the first trenches 36 may be adjusted in consideration of an etching depth during a trenching process and uniformity of the semiconductor substrate.

As shown in example FIG. 3B, next, a copper seed layer may be formed over the whole surface of the patterned first photoresist 35 including the first trenches 36. In addition, a second copper thin film 41a may be formed by an electroplating method. When performing the electroplating, it may be necessary to deposit a stable and clean copper seed layer.

Alternatively, after a diffusion prevention layer and the copper seed layer are deposited using equipment including a physical vapor deposition (PVD) chamber and a chemical vapor deposition (CVD) chamber, copper electroplating may be performed using copper electroplating equipment.

More specifically, the second copper thin film 41a may be formed by depositing copper over the copper seed layer by a metal-organic chemical vapor deposition (MOCVD) method or an electroplating method without breaking the vacuum after forming the copper seed layer. Here, when the copper thin film is deposited by the MOCVD method, temperature of the deposition is set to 50˜300° C. while using a precursor of 5˜100 sccm (standard cubic centimeter per minute). Here, (hfac) CuTMVS, a mixture of (hfac) CuTMVS and an additive, (hfac) CuVTMOS, a mixture of (hfac) CuVTMOS and an additive, (hfac) CuPENTENE or a mixture of (hfac) CuPENTENE and an additive may be used for the precursor.

In the case of using the electroplating method for deposition of the copper thin layer, the copper seed layer may be formed and the copper may be deposited at a low temperature of −20 to 150° C., without breaking the vacuum.

Otherwise, the second copper thin film 41a may be structured by further forming a barrier metal film of a conductive material over the whole surface of the first photoresist 35 including the first trenches 36, and then forming the copper seed layer. The barrier metal film may be formed, for example, by depositing TiN, Ta, TaN, WN_{X}, TiAl (N) and the like to a thickness of 10 to 1000 Å using the PVD or CVD method. The barrier metal film helps prevent copper atoms of the second copper thin film 41a which will be formed later from diffusing toward the interlayer dielectric 34.

Next, the first photoresist 35 over the interlayer dielectric 34 may be removed, for example, by etching, thereby removing the first photoresist 35 and also the copper thin layer existing over the first photoresist 35. For example, a lift-off method may be used to remove the first photoresist 35 and the copper thin layer existing over the first photoresist 35, such that the second copper thin film 41a remains only within the first trenches 36.

As an alternative, setting an upper surface of the interlayer dielectric 34 as a polishing stop, the CMP process may be performed to selectively polish the second copper thin film 41a and the barrier metal film. Accordingly, the second copper thin film 41a remains only in the trench 36.

As shown in example FIG. 3C, a second photoresist 37 is applied over the whole surface of the interlayer dielectric 34 including the second copper thin film 41a. Then, the second photoresist 37 is patterned through lithography and development. Here, the second photoresist 37 is patterned to be removed from upper surfaces of the second copper thin film 41a and the contact areas 24A and 24B. More specifically, the second photoresist 37 is patterned to be removed from the upper surface of the second copper thin film 41a and from upper surfaces of the contact areas 24A and 24B, but to remain only in the other areas 20 and 26.

As shown in example FIG. 3D, a via hole 42 may be formed by removing the interlayer dielectric 34 and the silicon nitride film 33 from the contact areas 24A and 24B, using the patterned second photoresist 37 and the second copper thin film 41a as masks. Since the second copper thin film 41a is used as the mask for forming the via hole 42, the via hole 42 is self-aligned between the respective second copper thin films 41a.

Next, as shown in example FIG. 3E, after a copper seed layer is formed over the whole surface of the semiconductor substrate 31 which includes the second photoresist 37, the second copper thin film 41a and the via holes 42, a third copper thin film 41b is formed by electroplating. Here, as aforementioned, the third copper thin film 41b may be formed using CVD or PVD.

The third copper thin film 41b may be structured by further forming a barrier metal film of a conductive material over the whole surface of the semiconductor substrate 31 including the second photoresist 37, the second copper thin film 41a and the respective via holes 42, and then forming the copper seed layer. As previously mentioned, the barrier metal film may be formed by depositing TiN, Ta, TaN, WNX, TiAl (N) and the like by a thickness of 10 to 1000 Å using CVD or PVD. Also, the barrier metal film prevents copper atoms of the third copper thin film 41b from diffusing toward the interlayer dielectric 34.

Setting an upper surface of the interlayer dielectric 34 as a polishing stop, the CMP process may be performed to selectively polish the third copper thin film 41b and the barrier metal film. Accordingly, the third copper thin film 41b remains only in the via holes 42. That is, a second copper line 41 including the second copper thin film 41a and the third copper thin film 41b is electrically connected with the first copper line 32.

Hereinafter, the metal line of the semiconductor device and a manufacturing method thereof according to embodiments will be described with reference to the accompanying drawings. The semiconductor device according to embodiments includes a semiconductor substrate 31, a first copper line 32, a silicon nitride film 33, an interlayer dielectric 34 and a second copper line 41. The interlayer dielectric 34 is formed over the whole surface of the semiconductor substrate 31 including the first copper line 32. The second copper line 41 includes the second copper thin film 41a and the third copper thin film 41b. The second copper thin film 41a is formed within the trench areas 22A through 22D by a predetermined depth from the surface of the interlayer dielectric 34. The third copper thin film 41b is formed in the contact areas 24A and 24B between the respective trench areas 22A through 22D so as to be connected to the second copper thin film 41a and the first copper line 32. Accordingly, the second copper line 41 including the second copper thin film 41a and the third copper thin film 41b can be in electric connection with the first copper line 32.

According to embodiments as described above, since a second copper thin film is formed between first copper thin films in connection with the first copper thin films by using a first copper thin film formed in a trench as a mask, misalignment of masks are minimized during formation of the metal line. Consequently, the error rate is minimized while improving the yield rate.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming an interlayer dielectric layer over the whole surface of a semiconductor substrate including a first metal line;
forming a plurality of trenches in trench areas each having a predetermined depth from a surface thereof by selectively removing portions of the interlayer dielectric layer;
forming a first metal film in the plurality of trenches;
forming a first photoresist pattern over the interlayer dielectric layer exposing contact areas and the first metal line;
forming via holes in the contact areas by etching the interlayer dielectric layer using the first photoresist pattern and the first metal film as masks; and
forming a second metal film in the via holes.

2. The method of claim 1, comprising removing the first photoresist pattern, and the second metal film formed over the first photoresist pattern and the first metal film by polishing.

3. The method of claim 1, wherein the first metal line and the first and the second metal films are formed of copper.

4. The method of claim 1, wherein the first metal film and the second metal film form a second metal line which is connected to the first metal line.

5. The method of claim 1, wherein the interlayer dielectric layer comprises at least one of an oxide layer, fluoro-silicate glass, and a low K material.

6. The method of claim 1, wherein forming the trench comprises:
forming a photoresist pattern over an upper part of the interlayer dielectric layer to expose the trench areas; and
forming the trenches by etching the interlayer dielectric layer using the photoresist pattern as a mask.

7. The method of claim 1, wherein forming the first metal film comprises:
forming a copper seed layer in the trenches; and
forming the first metal film over the copper seed layer by electroplating.

8. The method of claim 7, wherein the copper seed layer may be formed and the copper may be deposited at a temperature between about −20° C. to 150° C.

9. The method of claim 1, wherein forming the first metal film comprises:
forming a copper seed layer in the plurality of trenches; and
forming the first metal film by depositing copper over the copper seed layer using an metal-organic chemical vapor deposition method.

10. The method of claim 9, wherein the metal-organic chemical vapor deposition method is performed at a deposition temperature of about 50° C.˜300° C. using a precursor at about 5˜100 standard cubic centimeters per minute.

11. The method of claim 10, wherein the precursor comprises (hfac) CuTMVS or a mixture of (hfac) CuTMVS and an additive.

12. The method of claim 10, wherein the precursor comprises (hfac) CuVTMOS or a mixture of (hfac) CuVTMOS and an additive.

13. The method of claim 10, wherein the precursor comprises (hfac) CuPENTENE or a mixture of (hfac) CuPENTENE and an additive.

14. The method of claim 1, comprising forming a silicon nitride film over the whole surface of the first metal line,
wherein the via hole is formed by etching the silicon nitride film in the contact areas.

15. The method of claim 1, wherein the second metal film is formed using chemical vapor deposition.

16. The method of claim 1, wherein the second metal film is formed using physical vapor deposition.

17. An apparatus comprising:
an interlayer dielectric layer formed over the whole surface of a semiconductor substrate including a first metal line;
a first metal film formed in trench areas to a predetermined depth from a surface of the interlayer dielectric layer; and
a second metal film formed in contact areas disposed between the trench areas so as to be connected to the first metal film and the first metal line,
wherein the first metal film and the second metal film form a second metal line connected to the first metal line.

18. The apparatus of claim 17, wherein the first metal line and the first and the second metal films are formed of copper.

19. The apparatus of claim 17, wherein the interlayer dielectric comprises at least one of an oxide layer, fluoro-silicate glass, and a low K material.

20. The apparatus of claim 17, wherein the first metal film and the second metal film comprise a copper seed layer.
